(19) United States
(12) Patent Application Publication
(10) Pub. No.: US 2025/0081851 A1
(43) Pub. Date: Mar. 6, 2025

(54) THERMAL IMAGE SENSOR AND METHOD OF MANUFACTURING THE SAME

(71) Applicant: SAMSUNG ELECTRONICS CO., LTD., Suwon-si (KR)

(72) Inventors: Choong Ho RHEE, Suwon-si (KR); Jae Chul PARK, Suwon-si (KR); Byong Gwon SONG, Suwon-si (KR); Jang Woo YOU, Suwon-si (KR); Yong Seop YOON, Suwon-si (KR); Du Hyun LEE, Suwon-si (KR)

(73) Assignee: SAMSUNG ELECTRONICS CO., LTD., Suwon-si (KR)

(21) Appl. No.: 18/531,187

(22) Filed: Dec. 6, 2023

(30) Foreign Application Priority Data
Aug. 31, 2023 (KR) 10-2023-0115645

(51) Int. Cl. H10N 19/00

(52) U.S. Cl. CPC H10N 19/00

(57) ABSTRACT

A thermal image sensor and a method of manufacturing the same. The thermal image sensor includes: a substrate; a row electrode and a column electrode on the substrate; a multi-layer stack including an absorption layer and a temperature sensor; supporting arms that extend from diagonal corners of the multi-layer stack and that are spaced apart from both sides of the multi-layer stack, wherein the supporting arms have a concave-convex shape including a plurality of concave portions and a plurality of convex portions; and legs protruding from the row electrode and the column electrode, wherein the legs are connected to extended ends of the supporting arms to allow the multi-layer stack to float above the substrate.

### CROSS-REFERENCE TO RELATED APPLICATION(S)

This application is based on and claims priority under 35 U.S.C. § 119 to Korean Patent Application No. 10-2023-0115645, filed on Aug. 31, 2023, in the Korean Intellectual Property Office, the disclosure of which is incorporated by reference herein in its entirety.

### BACKGROUND

### 1. Field

The following description relates to a thermal image sensor, and more particularly, to a thermal image sensor having a floating support structure.

### 2. Description of Related Art

A thermal image sensor may convert received light energy having a predetermined wavelength range into heat energy, and may output the heat energy to generate image data. For example, a bolometer-type thermal image sensor may include a multi-layer stack including an absorption layer and a temperature sensor, and a support allowing the multi-layer stack to float above a substrate for thermal isolation, and the like.

Received light energy having a predetermined wavelength range may be converted by the absorption layer into heat energy, and some portion of the heat energy may raise the temperature of the temperature sensor, and another portion of the heat energy may be released to the substrate through the support. However, if a large amount of heat energy is released through the support, heat energy absorbed by the absorption layer may be reduced, thereby resulting in a lower sensitivity to temperature.

Therefore, there is a need for a floating support structure that has structural rigidity and is capable of increasing temperature sensitivity by minimizing heat conduction.

### SUMMARY

Provided are a thermal image sensor having a floating support structure, and a method of manufacturing the thermal image sensor having the floating support structure.

Additional aspects will be set forth in part in the description which follows and, in part, will be apparent from the description, or may be learned by practice of the presented embodiments.

In accordance with an aspect of the disclosure, a thermal image sensor includes: a substrate: a row electrode and a column electrode on the substrate; a multi-layer stack including an absorption layer and a temperature sensor: supporting arms that extend from diagonal corners of the multi-layer stack and that are spaced apart from both sides of the multi-layer stack, wherein the supporting arms have a concave-convex shape including a plurality of concave portions and a plurality of convex portions; and legs protruding from the row electrode and the column electrode, wherein the legs are connected to extended ends of the supporting arms to allow the multi-layer stack to float above the substrate.

A supporting arm from among the supporting arms may include a conductive layer electrically connected to a leg from among the legs, and may have an undulating shape including a plurality of valley portions and a plurality of peak portions, wherein the plurality of valley portions are closer to the substrate than the plurality of peak portions.

The conductive layer may include a material having a thermal conductance determined based on at least one from among a size, shape, and a number of the plurality of valley portions and the plurality of peak portions.

A height of the plurality of peak portions may be greater than or equal to a height of the legs.

The absorption layer may be on the conductive layer, and the plurality of valley portions may be partially exposed from the absorption layer.

The plurality of valley portions may include a hole.

Thermal isolation holes may be patterned in the absorption layer of the multi-layer stack.

The supporting arms may include an additional temperature sensor.

The additional temperature sensor may include Magnetic Tunnel Junctions (MTJ) elements, and the MTJ elements may be on the plurality of peak portions of the conductive layer.

The supporting arms may be equal to half of a length of the multi-layer stack.

The temperature sensor may include an MTJ element array including the MTJ elements connected to each other.

The temperature sensor may include a thermal resistance layer.

In accordance with an aspect of the disclosure, a method of manufacturing a thermal image sensor includes: forming a row electrode, a column electrode, and an insulation layer on a substrate: sequentially stacking a sacrificial layer and a first absorption layer on the insulation layer: forming via holes that expose the row electrode and the column electrode in the sacrificial layer and the first absorption layer, and forming legs in the via holes: forming trenches in the sacrificial layer: forming conductive layers corresponding to supporting arms on the trenches and connecting the conductive layers to the legs: forming a temperature sensor and a second absorption layer on the first absorption layer; and removing the sacrificial layer.

The method may further include, after the forming of the via holes, forming an additional sacrificial layer on the sacrificial layer and exposing the legs; and the trenches may be formed to extend from the additional sacrificial layer to the sacrificial layer.

The forming of the trenches may include adjusting a sidewall angle of the trenches based on etching process conditions.

The forming of the temperature sensor may include forming an MTJ element array including MTJ elements connected to each other.

The forming of the temperature sensor may include forming a thermal resistance layer.

At least one of the forming of the conductive layers and the removing of the sacrificial layer may include forming a hole in a bottom surface of valley portions of the conductive layers.

The forming of the second absorption layer may include patterning thermal isolation holes in the second absorption layer.

The forming of the temperature sensor may include forming the MTJ elements at peak portions of the conductive layers.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a perspective view of a thermal image sensor, according to an embodiment.

FIG. 2 is a plan view of FIG. 1, according to an embodiment.

FIG. 3A is a cross-sectional view taken along line A-A of FIG. 2, according to an embodiment.

FIG. 3B is a cross-sectional view taken along line B-B of FIG. 2, according to an embodiment.

FIG. 4 is a cross-sectional view of a conductive layer selected from a supporting arm, according to an embodiment.

FIG. 5 is a cross-sectional view of another example of a conductive layer of supporting arms, according to an embodiment.

FIG. 6 is a perspective view of another example of supporting arms having different lengths, according to an embodiment.

FIG. 7 is a plan view illustrating an example of a temperature sensor formed on a multi-layer stack, according to an embodiment.

FIG. 8 is a cross-sectional view of FIG. 7, according to an embodiment.

FIG. 9 is a plan view illustrating another example of a temperature sensor formed in a multi-layer stack, according to an embodiment.

FIG. 10 is a cross-sectional view of FIG. 9, according to an embodiment.

FIG. 11 is a plan view illustrating an example of an additional temperature sensor formed on a conductive layer of supporting arms, according to an embodiment.

FIG. 12 is a cross-sectional view of FIG. 11, according to an embodiment.

FIG. 13 is a cross-sectional view illustrating an example of holes formed in a conductive layer of supporting arms, according to an embodiment.

FIG. 14 is a plan view illustrating an example of thermal isolation holes formed in a multi-layer stack, according to an embodiment.

FIG. 15 is a plan view illustrating another example of thermal isolation holes formed in a multi-layer stack, according to an embodiment.

FIGS. 16A to 16G are cross-sectional views explaining a method of manufacturing a thermal image sensor according to an embodiment of the present disclosure, according to an embodiment.

FIGS. 17A to 17D are cross-sectional views explaining another example of a method of forming a conductive layer, according to an embodiment.

FIGS. 18 to 20 are cross-sectional views illustrating configuration examples of a packaged thermal image sensor according to an embodiment of the present disclosure, according to an embodiment.

### DETAILED DESCRIPTION

Details of various embodiments are included in the following detailed description and drawings. Advantages and features of the present disclosure, and a method of achieving the same, will be more clearly understood from the following embodiments described in detail with reference to the accompanying drawings. Throughout the drawings and the detailed description, unless otherwise described, the same drawing reference numerals may be understood to refer to the same elements, features, and structures.

Although the terms, “first,” “second,” etc., may be used herein to describe various elements, these elements should not be limited by these terms. These terms are only used to distinguish one element from another. Any references to singular may include plural unless expressly stated otherwise.

In addition, unless explicitly described to the contrary, an expression such as “comprising” or “including” will be understood to imply the inclusion of stated elements but not the exclusion of any other elements. Also, the terms, such as “unit” or “module,” etc., should be understood as a unit that performs at least one function or operation and that may be embodied as hardware, software, or a combination thereof.

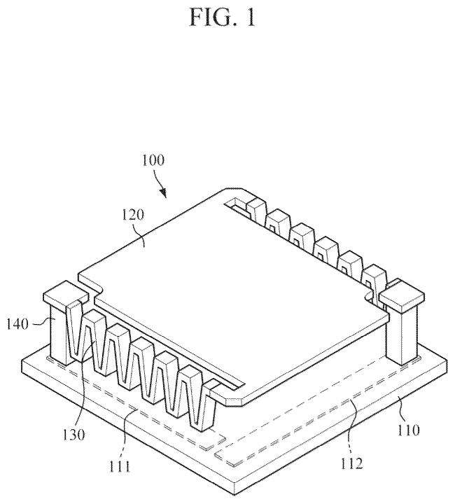

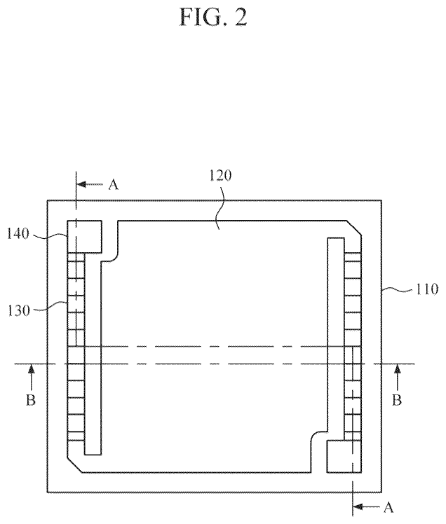

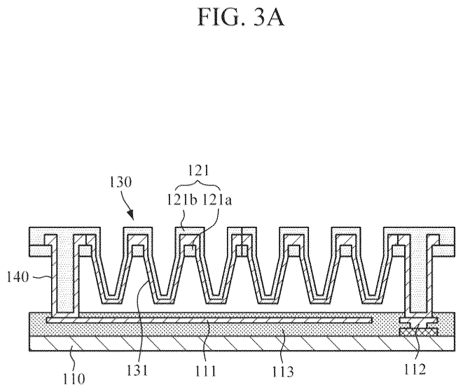

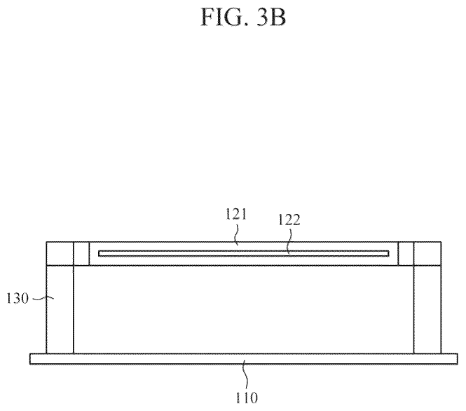

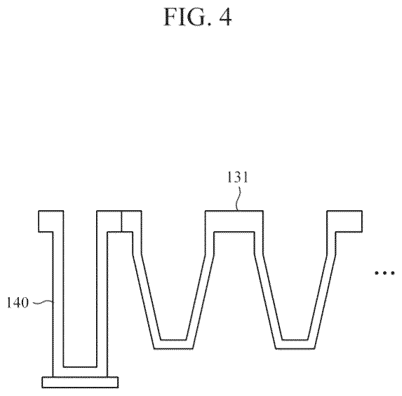

FIG. 1 is a perspective view of a thermal image sensor according to an embodiment of the present disclosure. FIG. 2 is a plan view of FIG. 1. FIG. 3A is a cross-sectional view taken along line A-A of FIG. 2. FIG. 3B is a cross-sectional view taken along line B-B of FIG. 2. FIG. 4 is a cross-sectional view of a conductive layer selected from supporting arms.

Referring to FIGS. 1 to 4, a thermal image sensor 100 according to an embodiment of the present disclosure may include a substrate 110, a multi-layer stack 120, supporting arms 130, and legs 140. Here, the thermal image sensor 100 may correspond to a unit pixel included in a thermal image sensor array.

A row electrode 111 and a column electrode 112 may be formed on the substrate 110. The row electrode 111 and the column electrode 112 may be in the form of strips, and may be arranged orthogonal to each other. An insulating layer 113 may be on the row electrode 111 and the column electrode 112. For example, the row electrode 111 and the column electrode 112 may be covered by the insulating layer 113. The substrate 110 may include a material such as silicon and the like.

In embodiments, an infrared radiation reflective layer may be formed on the substrate 110. The row electrode 111 and the column electrode 112 may include various known conductive materials.

The row electrode 111 and the column electrode 112 may be electrically connected to a temperature sensor 122 through the legs 140 and the supporting arms 130. In embodiments, the temperature sensor 122 may be any sensing unit, sensing module, or sensor that is temperature-sensitive. The row electrode 111 and the column electrode 112 may apply a bias voltage so that a current change due to a resistance change of the temperature sensor 122 may be detected by a Read-Out Integrated Circuit (ROIC).

The multi-layer stack 120 may include an absorption layer 121 and the temperature sensor 122. The absorption layer 121 may absorb entering or received light having a wavelength in a predetermined wavelength range. For example, the absorption layer 121 may absorb light having the infrared wavelength. Light energy, absorbed by the absorption layer 121 may be converted into heat energy to raise a temperature of the temperature sensor 122. The absorption layer 121 may include silicon nitride and the like.

A resistance value of the temperature sensor 122 may change with a change in temperature, thereby allowing the temperature sensor 122 to detect temperature. Examples of the temperature sensor 122 are described below.

The supporting arms 130 may extend from diagonal corners of the multi-layer stack 120 and spaced apart from both sides of the multi-layer stack 120. The supporting arms 130 may electrically connect the temperature sensor 122 to the legs 140. The supporting arms 130, except the portions connected to the multi-layer stack 120, may have a uniform width and may be spaced apart by a predetermined distance from both sides of the multi-layer stack 120.

The supporting arms 130 may have a concave-convex shape in which concave and convex portions are repeatedly formed. The respective supporting arms 130 may have an undulating or oscillating shape such as a waveform or a wave-like shape having valley portions that are close to the substrate 110 and peak portions that are far from the substrate 110. For example, the shape of the supporting arms 130 may be a shape that rises and falls in a first direction as the shape extends in a second direction perpendicular to the first direction. An example is illustrated in which the supporting arms 130 have a trapezoidal waveform or wave-like shape, but may have various waveforms or wave-like shapes such as a square waveform or wave-like shape, and the like.

The received light having the wavelength in the predetermined wavelength range may be converted by the absorption layer 121 into heat energy, and some portion of the heat energy may raise the temperature of the temperature sensor 122, and another portion of the heat energy may be released to the substrate 110 through the supporting arms 130.

In embodiments of the present disclosure, the supporting arms 130 may have a concave-convex shape in which concave portions and convex portions are repeatedly formed, and therefore the supporting arms 130 may be effective in increasing thermal resistance and controlling a direction of heat conduction, compared to supporting arms having a flat shape as a comparative example. In addition, compared to the comparative example, the supporting arms 130 in this embodiment may increase an area of the absorption layer 121, thereby further increasing an absorption amount. Accordingly, the supporting arms 130 according to embodiments of the present disclosure may improve structural rigidity as well as minimize heat conduction, thereby further increasing sensitivity to temperature.

The respective supporting arms 130 may be longer than a half of a length of the multi-layer stack 120. The portions of the supporting arms 130 that are connected to corners of the multi-layer stack 120 may have a length that is a half-cycle of the waveform. Accordingly, the supporting arms 130 may have a maximum length while stably supporting the multi-layer stack 120, thereby ensuring a maximum heat conduction path.

As an example, based on a result of thermal simulation performed on the supporting arms 130, a temperature reached by the temperature sensor 122 may increase about twice while increasing the area of the absorption layer 121, compared to supporting arms having a flat shape as a comparative example. Accordingly, the influence of noise equivalent temperature difference (NETD) may be maintained by the area of the absorption layer 121.

The legs 140 may protrude on the row electrode 111 and the column electrode 112, and may be connected to extended ends of the supporting arms 130, thereby allowing the multi-layer stack 120 to float above the substrate 110. The legs 140 may allow the multi-layer stack 120 to float a distance from the substrate 110 corresponding to one quarter of an incident wavelength 2, which may be for example a wavelength within the predetermined wavelength range.

A specific example of the supporting arms 130 is described below. The respective supporting arms 130 may include a conductive layer 131. The conductive layer 131 may be electrically connected to the legs 140, and may have an undulating shape such as a waveform or wave-like shape having one or more valley portions and one or more peak portions, wherein the one or more valley portions are closer to the substrate 110 than the one or more peak portions. The conductive layer 131 may have a uniform thickness. The absorption layer 121 may be on the conductive layer 131, and the one or more valley portions may be partially exposed from the absorption layer. For example, the conductive layer 131 may be covered by the absorption layer 121 such that the valley portions are partially exposed.

The absorption layer 121 may include a first absorption layer 121a a second absorption layer 121b, and the first absorption layer 121a may be closer to the substrate 110 than the second absorption layer. A portion of the first absorption layer 121a may be on or may cover the valley portions of the conductive layer 131 while partially exposing the valley portions, and a portion of the second absorption layer 121b may be on the peak portions of the conductive layer 131, for example by entirely covering the peak portions of the conductive layer 131, thereby forming the supporting arms 130 along with the conductive layer 131.

A height of the peak portions of the conductive layer 131 may be the same as a height of the legs 140. The conductive layer 131 may include a material having a relatively low thermal conductance. For example, the conductive layer 131 may include Titanium Nitride (Tin), nickel-chromium (Ni—Cr), and the like.

The relatively low thermal conductance of the conductive layer 131 may increase temperature sensitivity. The thermal conductivity of the conductive layer 131 may be selected or determined based on parameters such as a size, shape, and number of the valleys and peaks, etc., according to a total area, height, and the like of the multi-layer stack 120.

As is described below, the conductive layer 131 may be formed using a sacrificial layer that may be used for forming a cavity between the multi-layer stack 120 and the substrate 110. Compared to examples disclosed in U.S. Patent Publication No. 2009/0152467, the supporting arms 130 including the conductive layer 131 according to embodiments of the present disclosure may reduce thermal conductivity without applying an additional sacrificial layer.

Accordingly, the supporting arms 130 according to embodiments of the present disclosure may increase an absorption area in the thermal image sensor 100, and may be formed in the cavity between the multi-layer stack 120 and the substrate 110, thereby increasing a planar area as well as a vertical fill factor. In addition, the examples disclosed in U.S. Patent Publication No. 2009/0152467 may require additional processes, leading to an increase in costs and causing a significant structural change. By contrast, the supporting arms 130 according to embodiments of the present disclosure may improve temperature sensitivity without causing the above problems.

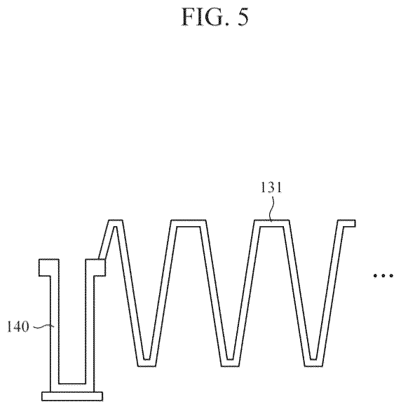

FIG. 5 is a cross-sectional view of another example of a conductive layer of supporting arms.

Referring to FIG. 5, a height of the peak portions of the conductive layer 131 may be greater than a height of the legs 140. The supporting arms 130 including the conductive layer 131 may increase thermal isolation for the same area or may increase an area of the absorption layer 121.

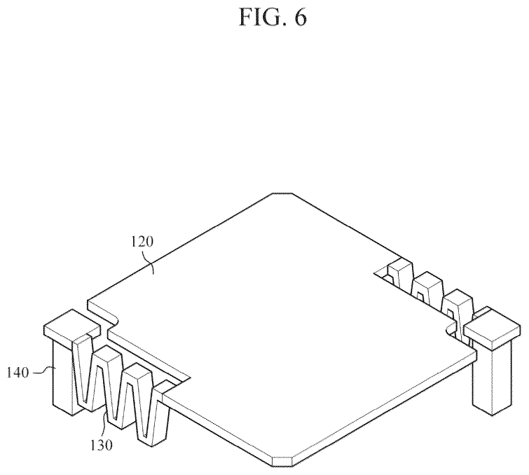

FIG. 6 is a perspective view of another example of supporting arms having different lengths.

Referring to FIG. 6, the respective supporting arms 130 may be shorter than a half of a length of the multi-layer stack 120. As an example, based on a result of thermal simulation performed on the supporting arms 130 having a length that is half the length of the multi-layer stack 120, a temperature reached by the temperature sensor 122 may increase by about 20%, compared to supporting arms having a flat shape as a comparative example. Accordingly, the length of the supporting arms 130 may be selected or determined according to the set thermal conductivity.

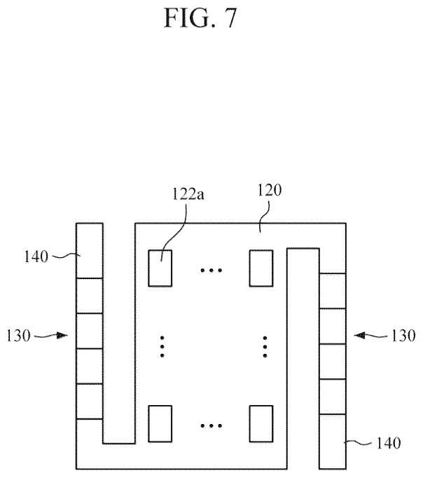

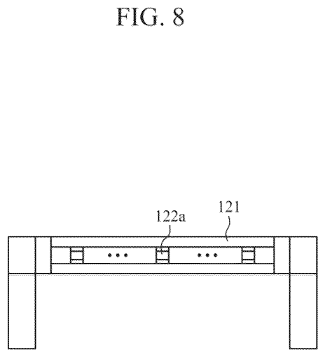

FIG. 7 is a plan view illustrating an example of a temperature sensor formed on a multi-layer stack. FIG. 8 is a cross-sectional view of FIG. 7.

Referring to FIGS. 7 and 8, the temperature sensor may include an MTJ element array including one or more MTJ elements 122a connected to each other. The MTJ elements 122a may be magnetoresistive elements having a resistance that changes with temperature.

The one or more MTJ elements 122a may include an upper magnetic layer, a lower magnetic layer, and a tunneling barrier layer formed therebetween. The magnetic layers may have an in-plane magnetization direction that is parallel to the plane of the substrate 110, or a perpendicular magnetization direction that is perpendicular to the plane of the substrate 110. The magnetic layers may be pinned layers with a fixed magnetization direction, or may be free layers in which magnetization direction may be switched to a direction parallel or antiparallel to the magnetization direction.

The MTJ element array may be formed with the MTJ elements 122a connected in series or in parallel with each other. The MTJ elements 122a may be arranged at equal intervals. The absorption layer 121 may be on the MTJ element array. For example, the MTJ element array may be covered by the absorption layer 121. The MTJ element array may be entirely covered by a portion of the first and second absorption layers 121a and 121b, to be buried therein.

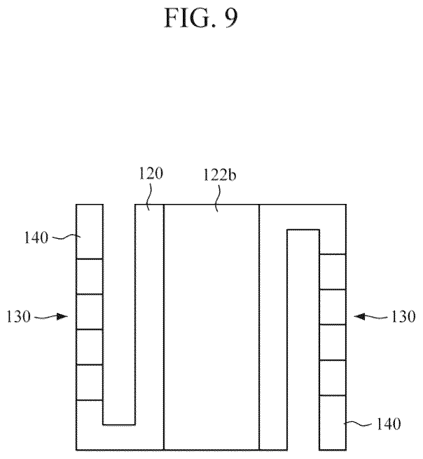

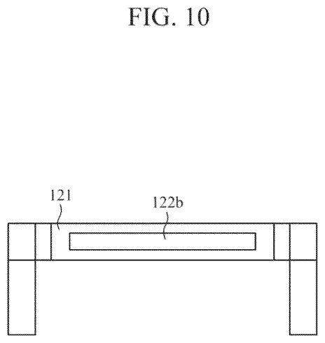

FIG. 9 is a plan view illustrating another example of a temperature sensor formed in a multi-layer stack. FIG. 10 is a cross-sectional view of FIG. 9.

Referring to FIGS. 9 and 10, the temperature sensor may include a heat resistance layer 122b. The heat resistance layer 122b may include VOx or Amorphous Silicon (a-Si), or the like. The heat resistance layer 122b may have a uniform width and may be disposed parallel to the supporting arms 130. The absorption layer 121 may be on the heat resistance layer 122b. For example, the heat resistance layer 122b may be covered by the absorption layer 121. The heat resistance layer 122b may be covered by a portion of the first and second absorption layers 121a and 121b, such that it is buried therein.

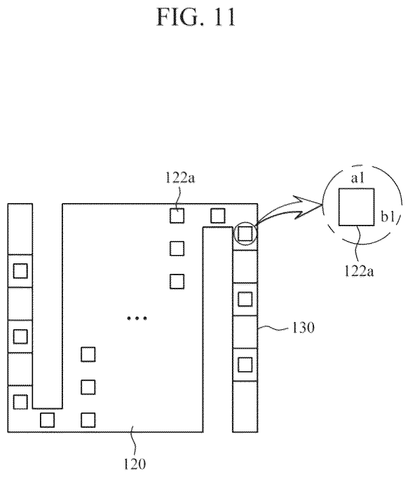

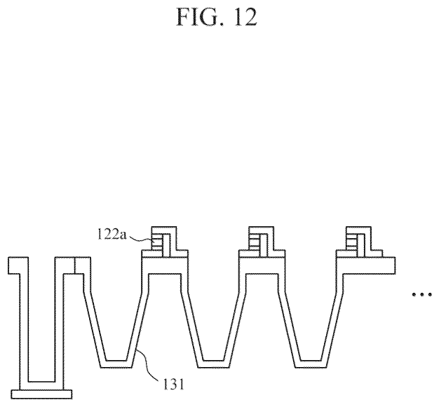

FIG. 11 is a plan view illustrating an example of an additional temperature sensor formed on a conductive layer of supporting arms. FIG. 12 is a cross-sectional view of FIG. 11.

As illustrated in FIGS. 11 and 12, the respective supporting arms 130 may include an additional temperature sensor. The additional temperature sensor may include MTJ elements 122a. The MTJ elements 122a may be disposed on one or more peak portions of the conductive layer 131. Accordingly, the thermal image sensor 100 may further increase a temperature sensing area. A width of the supporting arm 130 may be greater than a width al of the MTJ elements 122a, and a length of each of the one or more the peak portions of the supporting arm 130 may be greater than a length b1 of the MTJ elements 122a.

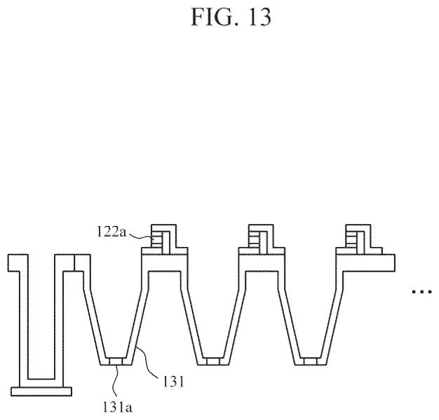

FIG. 13 is a cross-sectional view illustrating an example of holes formed in a conductive layer of supporting arms.

As illustrated in FIG. 13, holes 131a may be formed in valley portions of the conductive layer 131. The holes 131a of the conductive layer 131 may allow for thermal isolation. The holes 131a of the conductive layer 131 may increase a heat conduction path of the supporting arms 130, thereby improving temperature sensitivity and responsivity.

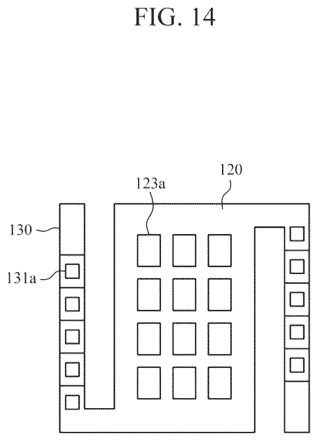

FIG. 14 is a plan view illustrating an example of thermal isolation holes formed in a multi-layer stack.

As illustrated in FIG. 14, thermal isolation holes 123a may be patterned in the absorption layer 121 of the multi-layer stack 120. The thermal isolation holes 123a having a mesh shape may be formed in the absorption layer 121. The thermal isolation holes 123a may increase a heat conduction path from the multi-layer stack 120 to the supporting arms 130, thereby improving temperature sensitivity and responsivity.

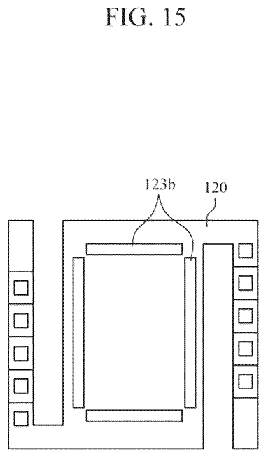

In another example, as illustrated in FIG. 15, thermal isolation holes 123b formed in the absorption layer 121 of the multi-layer stack 120 may be strip-shaped and formed on each edge of the multi-layer stack 120. In yet another example, all of the thermal isolation holes 123a that are mesh-shaped and the thermal isolation holes 123b that are strip-shaped may be formed in the absorption layer 121 of the multi-layer stack 120.

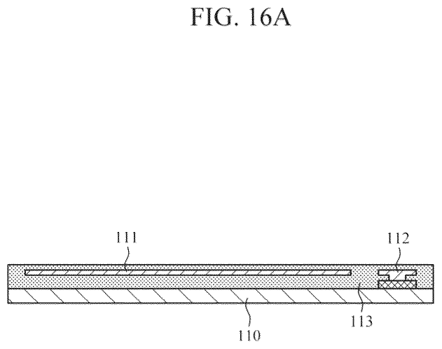

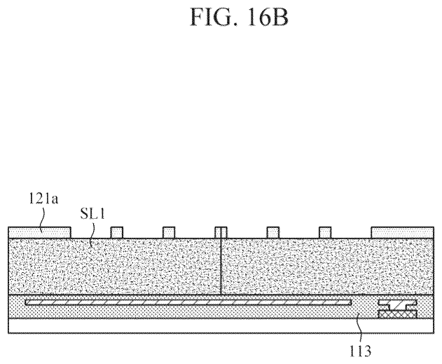

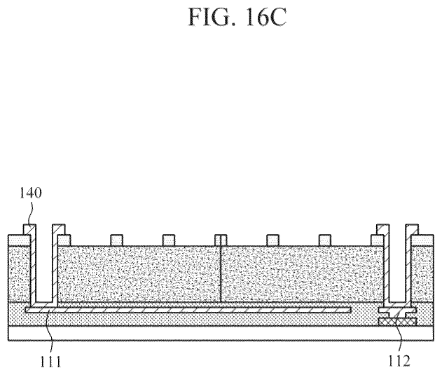

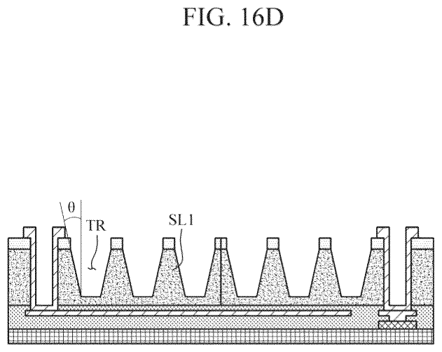

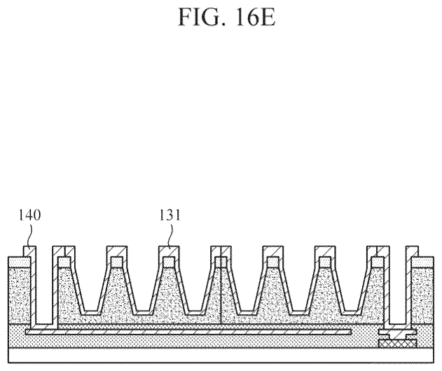

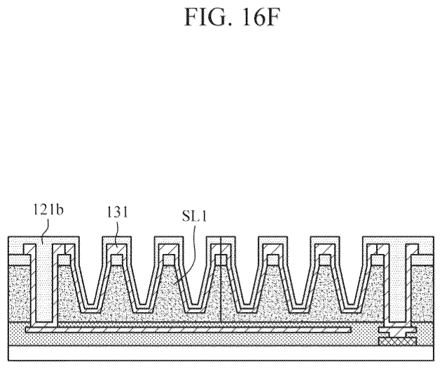

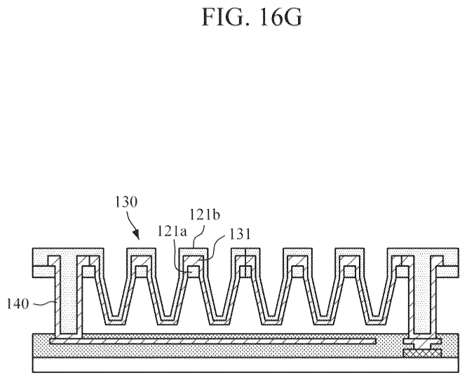

A method of manufacturing the thermal image sensor 100 according to an embodiment of the present disclosure is described below with reference to FIGS. 16A to 16G.

First, as illustrated in FIG. 16A, the row electrode 111 and the column electrode 112 may be formed on the substrate 110 along with the insulating layer 113. The insulating layer 113 may be on the row electrode 111 and the column electrode 112. For example, the row electrode 111 and the column electrode 112 may be covered by the insulating layer 113 for electrical isolation.

Then, as illustrated in FIG. 16B, a sacrificial layer SL1 and the first absorption layer 121a may be sequentially stacked on the insulating layer 113. In this case, the sacrificial layer SL1 and the first absorption layer 121a may be formed by deposition and the like.

The sacrificial layer SL1 may include an amorphous carbon layer (ACL) or a-Si, and the like. The sacrificial layer SL1 may be removed by a subsequent etching process, such that a separation space may be formed between the multi-layer stack 120 and the supporting arms 130, and a cavity may be formed between the substrate 110 and the multi-layer stack 120.

The first absorption layer 121a may be patterned to expose a portion of the sacrificial layer SL1 corresponding to the separation space between the multi-layer stack 120 and the supporting arms 130. In addition, the first absorption layer 121a may be patterned to expose a portion of the sacrificial layer SL1 corresponding to trenches TR formed in the sacrificial layer SL1.

Subsequently, as illustrated in FIG. 16C, via holes for exposing the row electrode 111 and the column electrode 112 may be formed in the sacrificial layer SL1 and the first absorption layer 121a, and then the legs 140 may be formed in the via holes.

The legs 140 may be patterned by deposition and the like, to be connected to the row electrode 111 and the column electrode 112. The legs 140 may include a conductive material which may be electrically connected to the row electrode 111 and the column electrode 112. The legs 140 may have a hollow space or may be completely filled in the via holes without the hollow space.

Next, as illustrated in FIG. 16D, trenches TR for forming the supporting arms 130 may be formed in the sacrificial layer SL1. The trenches TR may allow the supporting arms 130 to have a waveform or wave-like shape, as discussed above.

The trenches TR may be formed by an etching process. While the trenches TR are formed, a sidewall angle θ of the trenches TR may be adjusted based on etching process conditions for the sacrificial layer SL1. The etching process conditions for the sacrificial layer SL1 may be conditions including a material used as the sacrificial layer SL1, and the like. The trenches TR may be formed in a square shape or an inverted trapezoid, or the like.

Then, as illustrated in FIG. 16E, conductive layers 131 corresponding to the supporting arms 130 may be formed on the trenches TR, to be connected to the legs 140. The conductive layers 131 may be patterned by deposition and the like.

The conductive layers 131 may be continuously formed on the inside of the trenches TR and at connecting portions between the trenches TR, to form a waveform or wave-like shape having a uniform thickness. The conductive layers 131 may include Titanium Nitride (TiN), nickel-chromium (NiCr), and the like.

Subsequently, as illustrated in FIG. 16F, the temperature sensor 122 along with the second absorption layer 121b may be formed on the first absorption layer 121a. The second absorption layer 121b may be patterned by deposition and the like. The second absorption layer 121b may be patterned to expose a portion of the sacrificial layer SL1 corresponding to the separation space between the multi-layer stack 120 and the supporting arms 130. In the case where the legs 140 have a hollow space, the second absorption layer 121b may be filled in the hollow space of the legs 140.

In an embodiment, thermal isolation holes may be patterned in the second absorption layer 121b. The thermal isolation holes may be formed as the mesh-shaped holes 123a or the strip-shaped holes 123b. The supporting arms 130 may be formed by a portion of the second absorption layer 121b that corresponds to the conductive layers 131, along with the conductive layers 131 and a portion of the first absorption layer 121a.

The temperature sensor may be covered by the second absorption layer 121b. For example, a process of forming the temperature sensor may include a process of forming an MTJ element array including MTJ elements 122a connected to each other. In an additional embodiment, the MTJ elements 122a may be formed at portions corresponding to the peak portions of the conductive layer 131. In another example, a process of forming the temperature sensor 122 may include a process of forming a thermal resistance layer.

Then, as illustrated in FIG. 16G, the sacrificial layer SL1 may be removed. The sacrificial layer SL1 may be removed by an etching process. After the sacrificial layer SL1 is removed, the supporting arms 130 may be connected to diagonal corners of the multi-layer stack 120 and spaced apart from both sides of the multi-layer stack 120, and may have a waveform or wave-like shape with valley portions relatively close to the substrate 110 and peak portions relatively far from the substrate 110.

In an additional embodiment, if thermal isolation holes are formed in the bottom of the valley portions of the conductive layer 131, the holes may be formed in the bottom of the valley portions of the conductive layer 131 during the process of forming the conductive layers 131 for the supporting arms.

In another example, after the sacrificial layer SL1 is removed, the holes may be formed in the bottom of the valley portions of the conductive layer 131. In this case, when the sacrificial layer SL1 is removed, such that the valley portions of the conductive layer 131 are exposed from the first absorption layer 121a, the holes may be formed in the bottom of the valley portions of the conductive layer 131.

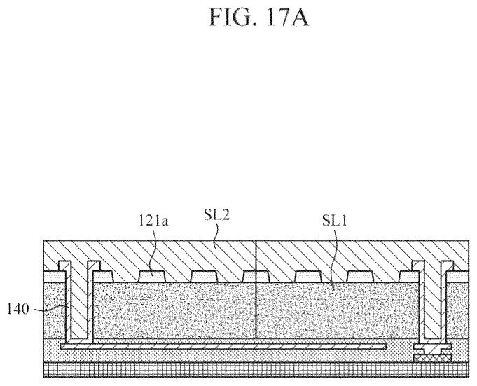

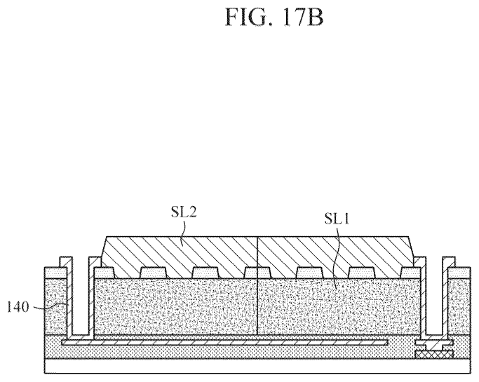

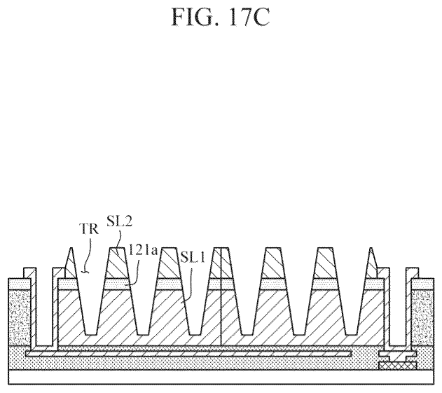

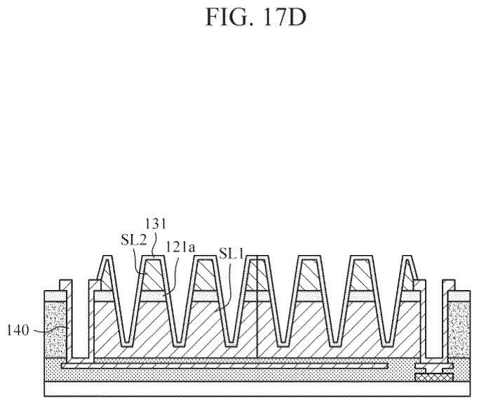

FIGS. 17A to 17D are cross-sectional views explaining another example of a method of forming a conductive layer.

As illustrated in FIG. 17A, after the legs 140 are formed in the via holes, an additional sacrificial layer SL2 may be formed on the sacrificial layer SL1. In this case, the additional sacrificial layer SL2 may also be stacked on the first absorption layer 121a. The additional sacrificial layer SL2 may be formed of ACL or a-Si, and the like, by deposition and the like.

Then, as illustrated in FIG. 17B, the legs 140 may be exposed. In this case, the legs 140 may be exposed in a process of etching the additional sacrificial layer SL2 using a pattern mask.

Subsequently, as illustrated in FIG. 17C, the trenches TR may be formed to extend from the additional sacrificial layer SL2 to the sacrificial layer SL1. In this case, the trenches TR may be formed by the etching process. While the trenches TR are formed, the additional sacrificial layer SL2 may be removed to expose the first absorption layer 121a.

Next, as illustrated in FIG. 17D, the conductive layers 131 for the supporting arms may be formed on the trenches TR, to be connected to the legs 140. Subsequent processes may be performed in a manner same as or similar to the above example. As a result, the peak portions of the conductive layer 131 corresponding to the supporting arms 130 may be formed at a greater height than the legs.

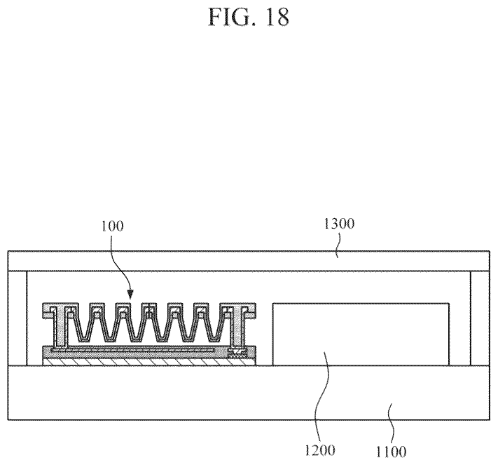

FIGS. 18 to 20 are cross-sectional views illustrating configuration examples of a packaged thermal image sensor according to an embodiment of the present disclosure.

For example, as illustrated in FIG. 18, the thermal image sensor 100 may be packaged such that the thermal image sensor 100 is mounted on a printed circuit board module 1100 along with a Read-Out Integrated Circuit (ROIC) 1200, and is covered by an IR transparent cap 1300. A lens, filter, or infrared (IR) coating, and the like may be applied to the IR transparent cap 1300.

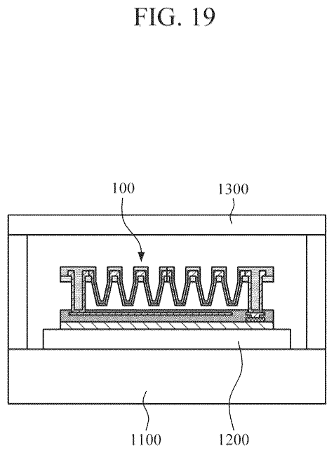

In another example, as illustrated in FIG. 19, the thermal image sensor 100 may be packaged such that the thermal image sensor 100 is mounted on the ROIC 1200 mounted on the printed circuit board module 1100, and is covered by the IR transparent cap 1300.

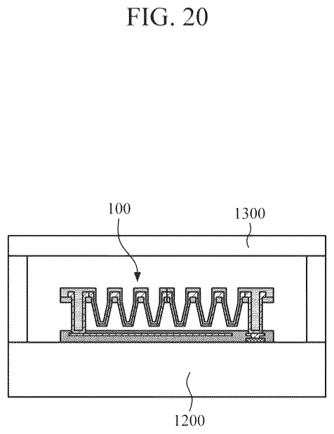

In yet another example, as illustrated in FIG. 20, the thermal image sensor 100 may be packaged such that the thermal image sensor 100 is mounted on the ROIC 1200 without the printed circuit board module 1100, and is covered by the IR transparent cap 1300.

The thermal image sensor 100 according to embodiments of the present disclosure may be applied to chip-type small thermal sensing elements and the like which require thermal isolation, and may be applied to final products (e.g., mobile phone, electronics, TV/monitor, AI speaker, refrigerator, etc.) which use temperature sensing or thermal image sensing.

The present disclosure has been described herein with regard to example embodiments. However, it will be obvious to those skilled in the art that various changes and modifications can be made without changing technical conception and essential features of the present disclosure. Thus, the above-described embodiments are illustrative in all aspects and are not intended to limit the present disclosure.

What is claimed is:

1. A thermal image sensor comprising:
a substrate;
a row electrode and a column electrode on the substrate;
a multi-layer stack comprising an absorption layer and a temperature sensor;
supporting arms that extend from diagonal corners of the multi-layer stack and that are spaced apart from both sides of the multi-layer stack, wherein the supporting arms have a concave-convex shape comprising a plurality of concave portions and a plurality of convex portions; and
legs protruding from the row electrode and the column electrode, wherein the legs are connected to extended ends of the supporting arms to allow the multi-layer stack to float above the substrate.

2. The thermal image sensor of claim 1, wherein a supporting arm from among the supporting arms comprises a conductive layer electrically connected to a leg from among the legs, and has an undulating shape comprising a plurality of valley portions and a plurality of peak portions, wherein the plurality of valley portions are closer to the substrate than the plurality of peak portions.

3. The thermal image sensor of claim 2, wherein the conductive layer comprises a material having a thermal conductance determined based on at least one from among a size, shape, and a number of the plurality of valley portions and the plurality of peak portions.

4. The thermal image sensor of claim 2, wherein a height of the plurality of peak portions is greater than or equal to a height of the legs.

5. The thermal image sensor of claim 2, wherein the absorption layer is on the conductive layer, and
wherein the plurality of valley portions are partially exposed from the absorption layer.

6. The thermal image sensor of claim 2, wherein the plurality of valley portions comprise a hole.

7. The thermal image sensor of claim 6, wherein thermal isolation holes are patterned in the absorption layer of the multi-layer stack.

8. The thermal image sensor of claim 2, wherein the supporting arms comprise an additional temperature sensor.

9. The thermal image sensor of claim 8, wherein the additional temperature sensor comprises Magnetic Tunnel Junctions (MTJ) elements,
wherein the MTJ elements are on the plurality of peak portions of the conductive layer.

10. The thermal image sensor of claim 1, wherein the supporting arms are equal to half of a length of the multi-layer stack.

11. The thermal image sensor of claim 1, wherein the temperature sensor comprises an MTJ element array comprising the MTJ elements connected to each other.

12. The thermal image sensor of claim 1, wherein the temperature sensor comprises a thermal resistance layer.

13. A method of manufacturing a thermal image sensor, the method comprising:
forming a row electrode, a column electrode, and an insulation layer on a substrate;
sequentially stacking a sacrificial layer and a first absorption layer on the insulation layer;
forming via holes that expose the row electrode and the column electrode in the sacrificial layer and the first absorption layer, and forming legs in the via holes;
forming trenches in the sacrificial layer;
forming conductive layers corresponding to supporting arms on the trenches and connecting the conductive layers to the legs;
forming a temperature sensor and a second absorption layer on the first absorption layer; and
removing the sacrificial layer.

14. The method of claim 13, further comprising:
after the forming of the via holes, forming an additional sacrificial layer on the sacrificial layer and exposing the legs; and
wherein the trenches are formed to extend from the additional sacrificial layer to the sacrificial layer.

15. The method of claim 13, wherein the forming of the trenches comprises adjusting a sidewall angle of the trenches based on etching process conditions.

16. The method of claim 13, wherein the forming of the temperature sensor comprises forming an MTJ element array comprising MTJ elements connected to each other.

17. The method of claim 13, wherein the forming of the temperature sensor comprises forming a thermal resistance layer.

18. The method of claim 13, wherein at least one of the forming of the conductive layers and the removing of the sacrificial layer comprises forming a hole in a bottom surface of valley portions of the conductive layers.

19. The method of claim 13, wherein the forming of the second absorption layer comprises patterning thermal isolation holes in the second absorption layer.

20. The method of claim 13, wherein the forming of the temperature sensor comprises forming the MTJ elements at peak portions of the conductive layers.
